(19) United States
(12) Patent Application Publication
(10) Pub. No.: US 2020/0364547 A1
(43) Pub. Date: Nov. 19, 2020

(54) CHIP INCLUDING NEURAL NETWORK PROCESSORS AND METHODS FOR MANUFACTURING THE SAME

(71) Applicants: ICLEAGUE Technology Co., Ltd., Jiaxing City (CN); AP Memory Technology Corp., Zhubei City (TW)

(72) Inventors: Wenliang CHEN, Jiaxing City (CN); Eugene Jinglun TAM, Jiaxing City (CN); Lin MA, Jiaxing City (CN); Joseph Zhifeng XIE, Jiaxing City (CN); Alessandro MINZONI, Jiaxing City (CN)

(73) Assignees: ICLEAGUE Technology Co., Ltd., Jiaxing City (CN); AP Memory Technology Corp., Zhubei City (TW)

(21) Appl. No.: 16/852,241

(22) Filed: Apr. 17, 2020

(30) Foreign Application Priority Data
May 17, 2019 (CN) 201910414660.7

(51) Int. Cl. G06N 3/063; H03K 19/0175; H03K 19/08; G11C 11/34

(52) U.S. Cl. CPC G06N 3/063; G11C 11/34; H03K 19/08; H03K 19/017545

(57) ABSTRACT

The present disclosure relates to a neural network artificial intelligence chip and a method for forming the same. The neural network artificial intelligence chip includes: a storage circuit, that includes a plurality of storage blocks; and a calculation circuit, that includes a plurality of logic units, the logic units being correspondingly coupled one-to-one to the storage blocks, and the logic unit being configured to acquire data in the corresponding storage block and store data to the corresponding storage block.

### CROSS-REFERENCE TO RELATED APPLICATION

This application is based upon and claims priority to Chinese Patent Application No. 201910414660.7, filed on May 17, 2019, the entire contents thereof are incorporated herein by reference.

### TECHNICAL FIELD

The present disclosure relates to the technical field of integrated circuits, and in particular, relates to chip including neural network artificial intelligence processors and methods for manufacturing the same.

### BACKGROUND

At present, artificial intelligence based on a deep neural network has been proven to tend to assist or replace human beings in many application fields, such as, automatic driving, image recognition, medical diagnosis, gaming, financial data analysis, search engine and the like. Although general chip structures based on the neural network have make remarkable achievements in the field of artificial intelligence, due to huge calculation amount and data amount, the calculation speed of the artificial intelligence chip is still facing a great challenge.

In a conventional artificial intelligence chip, generally data is stored in a dynamic random access memory (DRAM) memory outside a neural network calculation chip, and a storage chip and the neural network calculation chip are connected by a package connection line of an external interposer. Since the external interposer has a limited space, the number of connection lines and distance thereof are restricted. As a result, a bandwidth for data transmission between the DRAM memory and the neural network artificial intelligence chip is limited. In addition, since a great capacitance is present at an interface of the external interposer, the data transmission suffers from a great load, and as a result, power consumption is high. Further, the external package connection lines have a great capacitance and a high inductance, an upper limit of the data transmission and a lower limit of the power consumption are restricted. Furthermore, at present, in the calculation chip of the current neural network, data is transmitted and stored between an SRAM memory and the external DRAM memory. Therefore, the number of SRAM memories further limits a data transmission rate between the SRAM memory and the DRAM memory. For improvement of the calculation speed of the chip, a large number of SRAM memories need to be used. Since the SRAM memory takes up a large area of the chip, the cost and the power consumption may be increased.

These problems cause a great challenge for the calculation speed of the artificial intelligence chip.

### SUMMARY

The present disclosure is intended to provide a neural network artificial intelligence chip and a method for forming the neural network artificial intelligence chip, to improve a calculation speed of the chip.

In view of the above, the present disclosure provides a neural network artificial intelligence chip. The neural network artificial intelligence chip includes: a storage circuit, including a plurality of storage blocks; and a calculation circuit, including a plurality of logic units, wherein the logic units is one-to-one correspondingly connected to the storage blocks, and the logic unit is configured to acquire data in the corresponding storage block and store data to the corresponding storage block.

circuitcircuitcircuitcircuitcircuitcircuitcircuitcircuitFurther, the present disclosure further provides a method for forming a neural network artificial intelligence chip. The method includes: forming a calculation circuit, the calculation circuit including a plurality of logic units; forming a storage circuit, the storage circuit including a plurality of storage blocks; and one-to-one correspondingly connecting the plurality of logic units and the plurality of storage blocks.

In the neural network artificial intelligence chip according to the present disclosure, the storage circuit includes a plurality of storage blocks, and the calculation circuit includes a plurality of logic units. The logic units are one-to-one correspondingly connected to the storage blocks, and data transmission is carried out between the logic units and the corresponding storage blocks. In this way, a bandwidth for data transmission between the calculation circuit and the entire storage circuit is increased, and thus calculation capabilities of the chip are enhanced.

Further, the storage circuit and the calculation circuit are respectively disposed on different substrates, and are connected by 3D stacking and bonding, such that a connection path between the storage block and the logic unit is reduced. In this way, the connected load capacitor and inductor are both smaller, such that the data transmission rate and bandwidth are both increased, and power consumption is low.

### BRIEF DESCRIPTION OF THE DRAWINGS

FIG. 1 is a schematic structural diagrams of neural network artificial intelligence chips, according to specific embodiments of the present disclosure;

FIG. 2 is a schematic structural diagrams of neural network artificial intelligence chips, according to specific embodiments of the present disclosure; and

FIG. 3 is a schematic flowchart of a method for forming a neural network artificial intelligence chip, according to a specific embodiment of the present disclosure.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations consistent with the disclosure. Instead, they are merely examples of apparatuses and methods consistent with aspects related to the disclosure as recited in the appended claims.

The terminology used in the present disclosure is for the purpose of describing particular embodiments only and is not intended to limit the present disclosure. As used in the present disclosure and the appended claims, the singular forms “a,” “an,” and “the” are intended to include the plural forms as well, unless the context clearly indicates otherwise. It shall also be understood that the term “and/or” used herein is intended to signify and include any or all possible combinations of one or more of the associated listed items.

It shall be understood that, although the terms “first,” “second,” “third,” etc. may be used herein to describe various information, the information should not be limited by these terms. These terms are only used to distinguish one category of information from another. For example, without departing from the scope of the present disclosure, first information may be termed as second information; and similarly, second information may also be termed as first information. As used herein, the term “if” may be understood to mean “when” or “upon” or “in response to a judgment” depending on the context.

Hereinafter, specific embodiments of a neural network artificial intelligence chip and a method for forming the neural network artificial intelligence chip according to the present disclosure are described in detail with reference to the accompanying drawings.

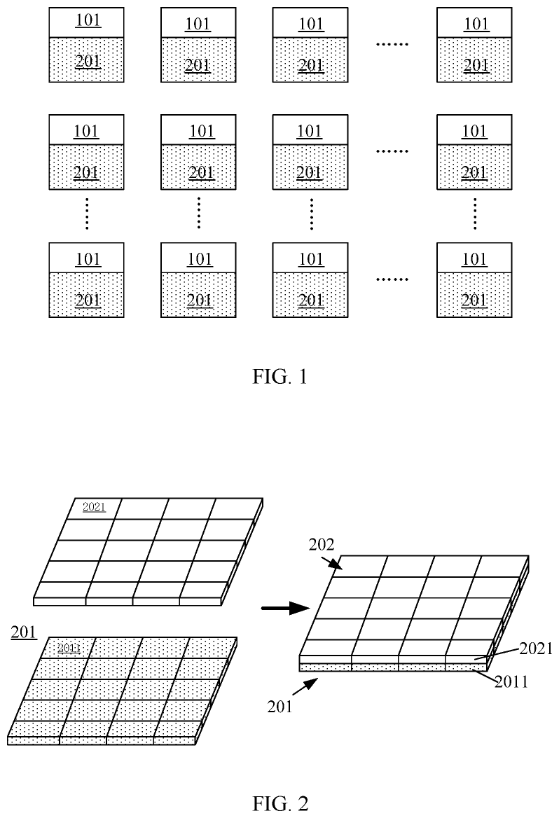

Referring to FIG. 1, FIG. 1 is a schematic structural diagram of a neural network artificial intelligence chip according to one specific embodiment of the present disclosure.

The artificial intelligence chip includes: a storage circuit, including a plurality of storage blocks 101; and a calculation circuit, including a plurality of logic units 102. The logic units 102 are one-to-one correspondingly connected to the storage blocks 101, and the logic unit 102 is configured to acquire data in the corresponding storage block 101 and store data to the corresponding storage block.

It should be noted that FIG. 1 is a schematic structural diagram of connections of functional circuits of the artificial intelligence chip according to this specific embodiment, rather than a schematic structural diagram of physical connections therebetween.

Since data transmission is carried out between each logic unit 102 and the corresponding storage block 101, including data reading and data storage, a bandwidth for data transmission between the entire calculation circuit and the entire storage circuit is increased. Each logic unit 102 and the storage block 101 are connected as a node of the neural network. Data calculation and transmission may be carried out for each node. A plurality of nodes constitute a neural network processing unit, such that the calculation speed of the artificial intelligence chip is improved.

The logic units 102 may be designated to implement different calculation functions. For example, some logic units 102 are configured to perform calculation, and some logic units 102 are configured to perform training. With respect to the functions and requirements of the logic units 102, a storage block having a suitable storage capability may be assigned to each logic unit 102.

The storage circuit is a DRAM storage circuit. In other specific embodiments, another type of storage circuit may be employed, for example, an magnetoresistive random-access memory (MRAM) storage circuit, a phase-change memory (PRAM)storage circuit or the like.

The logic unit 102 includes a multiplier, an accumulator, an operation logic circuit, a latch or the like device, and a circuit. In some specific embodiment, the logic unit 102 may further include an SRAM memory which is used as a cache for data transmission. In this specific embodiment of the present disclosure, the logic unit 102 may also not be provided with an SRAM memory. Since a transmission rate between the logic unit 102 and the storage block 101 is very high and the bandwidth is very high, no SRAM memory needs to be arranged in the logic unit 102, and the data in the storage block may be directly read and stored at a high speed.

In other specific embodiments, at least a portion of the logic units 102 may be connected to each other to satisfy functional requirements of the calculation circuit; and at least a portion of the storage blocks 101 may also be connected to each other to satisfy data storage requirements.

The storage circuit may be disposed on a substrate. By an isolation structure or a circuit connection structure or the like in the substrate, the storage circuit may be partitioned into a plurality of storage circuits 101, which may respectively implement data storage, data reading and data erase control separately.

The storage circuit and the calculation circuit may be respectively disposed on different dies, and then packaged on the same package substrate. By package lines on the package substrate, the storage blocks 101 are connected to the logic units 102.

For further reduction of the package lines and mitigation of restrictions caused by capacitors, inductors and the like to the transmission rate and the bandwidth, in this specific embodiment of the present disclosure, a 3D stacked artificial intelligence chip structure is further provided.

Referring to FIG. 2, FIG. 2 is a schematic structural diagram of a neural network artificial intelligence chip according to another specific embodiment of the present disclosure.

In this specific embodiment, the calculation circuit of the artificial intelligence chip is disposed in a logic substrate 201, and the storage circuit is disposed in a storage substrate 202, wherein the storage substrate 201 and the logic substrate 202 are connected by stacking and bonding.

Logic units 2011 and corresponding storage blocks are electrically connected by an interconnection structure in the logic substrate 201 and the storage substrate 202. An interconnection line, an interconnection post and the like interconnection structure are disposed in both the logic substrate 201 and the storage substrate 202.

In one specific embodiment, front surfaces of the logic substrate 201 and the storage substrate 202 are connected by mixing and bonding, metal bonding is disposed between interconnection structures exposed on the front surfaces of the logic substrate 201 and the storage substrate 202, inter-dielectric layer bonding is disposed between dielectric layers of the logic substrate 201 and the storage substrate 202, and logic units 2011 one-to-one correspond to storage blocks 2021 by the metal bonding between the interconnection structures while the logic substrate 201 and the storage substrate 202 are stacked and bonded.

In another specific embodiment, a passivation layer is disposed on each of the front surfaces of the logic substrate 201 and the storage substrate 202, and the logic substrate 201 and the storage substrate 202 are stacked and bonded by a bonding process between the two passivation layers. The storage block 2021 and the logic unit 2011 are correspondingly connected by a deep-hole connection structure passing through the storage substrate 202 and/or the logic substrate 201.

In another specific embodiment, a rear surface of any of the logic substrate 201 and the storage substrate 202 is connected to the front surface of the other substrate by bonding, and the storage block 2021 and the logic unit 2011 may be correspondingly connected by a deep-hole connection structure passing through the storage substrate 202 and/or the logic substrate 201.

In another specific embodiment, the logic substrate 201 and the storage substrate 202 of the artificial intelligence chip may be stackingly connected by other bonding or interconnection structures, and a person skilled in the art would make reasonable design according to the actual needs.

Since the logic unit 2011 and the storage block 2021 may be directly connected by the interconnection structure between the substrates, an I/O connection length may be greatly reduced. Generally, the length may be controlled to be within 3 μm, which greatly reduces power consumption of the connection circuit. In addition, since in an integrated circuit process, the interconnection line has a very small width, the number of connection lines between a single logic unit 2011 and the corresponding storage block 2021 may be very large, and the data interface is very wide, such that high-bandwidth data transmission may be implemented. In one specific embodiment, the transmission bandwidth may at least reach 4 Gbit/s.

In this specific embodiment, the interconnected logic unit 2011 and storage block 2021 are stacked over each other, which are respectively disposed on an upper layer and a lower layer, and one-to-one correspond to each other in a physical space. In another specific embodiment, based on suitable wiring paths in the logic substrate 201 and the storage substrate 202, the logic unit 2011 may not be perpendicularly stacked with the corresponding storage block 2021.

When the storage blocks 2021 have different storage capacities, sizes of the storage blocks 2021 may also be different, and sizes of different logic units 2011 may also be different.

In another specific embodiment, the storage blocks may also be disposed in a plurality of substrates 202 that are connected by stacking, such that the storage capacity of the storage circuit per unit area may be increased, and the size of the artificial intelligence chip may be reduced. Different storage substrates are connected by 3D stacking and bonding, such that each storage block 2021 has a plurality of sub-storage blocks, or a specific number of storage blocks 2021 are disposed in each storage substrate 202 such that the area of the storage circuit is reduced.

In another specific embodiment, the calculation circuit may also be disposed in a plurality of logic substrates 201, and different logic substrates 201 are connected by 3D stacking and bonding, such that circuits and devices of each logic unit 201 are distributed in the plurality of logic substrates, and are then connected by bonding. For example, an operation logic unit, a latch, an SRAM and the like in the logic unit 201 are respectively disposed in different logic substrates 201, and are then electrically connected by bonding of the substrate devices to form a single logic unit; or a specific number of logic units 2011 are disposed in each logic substrate 201, such that the area of calculation circuit is reduced.

The artificial intelligence chip further includes a plurality of storage logic circuits one-to-one correspondingly connected to the storage blocks. The storage logic circuits include: a storage block control circuit, a storage block repair circuit, a storage block internal power control circuit, a storage block test circuit and the like logic circuits. The storage logic circuits are independent of one another to respectively control the storage block separately. The storage logic circuits may also be connected to each other, such that the entire storage circuit is wholly controlled where necessary.

The storage logic circuits may be respectively disposed in the storage substrates 202 where the storage blocks 2021 are disposed. In another specific embodiment, the storage logic circuits may also be disposed in another storage circuit substrate, and the storage circuit substrate and the storage substrate may be connected by stacking and bonding, such that the storage logic circuits are one-to-one correspondingly connected to the storage blocks 2021.

The logic unit 2011 includes a multiplier, an accumulator, an operation logic circuit, a latch or the like device, and a circuit. In some specific embodiment, the logic unit 2011 may further include an SRAM memory which is used as a cache for data transmission. In this specific embodiment of the present disclosure, the logic unit 102 may also not be provided with an SRAM memory. Since a transmission rate between the logic unit 2011 and the storage block 2021 is very high and the bandwidth is very high, no SRAM memory needs to be arranged in the logic unit 2011, and the data in the storage block may be directly read and stored at a high speed.

In the neural network artificial intelligence chip according to the above specific embodiment, the storage circuit includes a plurality of storage blocks, and the calculation circuit includes a plurality of logic units. The logic units are one-to-one correspondingly connected to the storage blocks, and data transmission is carried out between the logic units and the corresponding storage blocks. In this way, a bandwidth for data transmission between the entire calculation circuit and the entire storage circuit is increased, and thus calculation capabilities of the chip are enhanced.

Further, the storage circuit and the calculation circuit are respectively disposed on different substrates, and are connected in a 3D stacking and bonding fashion, such that a connection path between the storage block and the logic unit is reduced. In this way, the connected load capacitor and inductor are both smaller, such that the data transmission rate and bandwidth are both increased, and power consumption is low.

A specific embodiment of the present disclosure further provides a method for forming the neural network artificial intelligence chip.

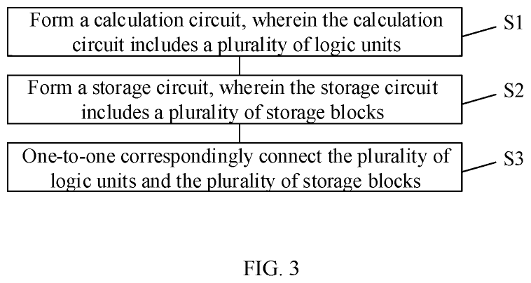

Referring to FIG. 3, a schematic flowchart of the method for forming the neural network artificial intelligence chip is illustrated.

The method includes the following steps:

Step S1: A calculation circuit is formed, wherein the calculation circuit includes a plurality of logic units.

The calculation circuit is disposed in the logic substrate. Specifically, the calculation circuit may be disposed in a single layer logic substrate, or may be disposed in a plurality of logic substrates and then the plurality of logic substrates are connected by stacking to form the calculation circuit.

Step S2: A storage circuit is formed, wherein the storage circuit includes a plurality of storage blocks.

The storage circuit is a DRAM storage circuit, an MRAM storage circuit, a PRAM storage circuit or the like dynamic storage circuits.

The storage circuit may be disposed in a single storage substrate.

The storage blocks may also be disposed in a plurality of substrates that are connected by stacking, such that the storage capacity of the storage circuit per unit area may be increased, and the size of the artificial intelligence chip may be reduced. Different storage substrates are connected by 3D stacking and bonding, such that each storage block has a plurality of sub-storage blocks, or a specific number of storage blocks are disposed in each storage substrate 202 such that the area of the storage circuit is reduced.

The artificial intelligence chip further includes a plurality of storage logic circuits one-to-one correspondingly connected to the storage blocks. The storage logic circuits include: a storage block control circuit, a storage block repair circuit, a storage block internal power control circuit, a storage block test circuit and the like logic circuits. The storage logic circuits are independent of one another to respectively control the storage block separately. The storage logic circuits may also be connected to each other, such that the entire storage circuit is wholly controlled where necessary.

The storage logic circuits may be respectively disposed in the storage substrate where the storage blocks are disposed. In another specific embodiment, the storage logic circuits may also be disposed in another storage circuit substrate, and the storage circuit substrate and the storage substrate may be connected by stacking and bonding, such that the storage logic circuits are one-to-one correspondingly connected to the storage blocks.

Optionally, step S1 may be performed first and then step S2 may be performed; or step S2 may be performed first and then step S1 may be performed; or for improvement of efficiency, step S1 and step S2 may be simultaneously performed.

Step S3: The plurality of logic units are one-to-one correspondingly connected to the plurality of storage blocks.

The logic unit is configured to acquire data in the corresponding storage block and store data to the corresponding storage block.

Specifically, the storage substrate and the logic substrate are connected by stacking and bonding, such that the plurality of logic units are one-to-one correspondingly connected to the plurality of storage blocks.

The logic unit and the corresponding storage block are electrically connected by an interconnection structure in the logic substrate and the storage substrate. An interconnection line, an interconnection post and the like interconnection structure are disposed in both the logic substrate 201 and the storage substrate.

Front surfaces of the logic substrate and the storage substrate are connected in a mixing and bonding fashion, metal bonding is disposed between interconnection structures exposed on the front surfaces of the logic substrate and the storage substrate, inter-dielectric layer bonding is disposed between dielectric layers of the logic substrate and the storage substrate, and logic units one-to-one correspond to storage blocks by the metal bonding between the interconnection structures while the logic substrate and the storage substrate are stacked and bonded.

A passivation layer may also be disposed on each of the front surfaces of the logic substrate and the storage substrate, and the logic substrate and the storage substrate are stacked and bonded by a bonding process between the two passivation layers. The storage block and the logic unit are correspondingly connected by a deep-hole connection structure passing through the storage substrate and/or the logic substrate.

A rear surface of any of the logic substrate and the storage substrate may also be connected to the front surface of the other substrate in a bonding fashion, and the storage block and the logic unit may be correspondingly connected by a deep-hole connection structure passing through the storage substrate and/or the logic substrate.

The interconnected logic unit and storage block are stacked over each other, which are respectively disposed on an upper layer and a lower layer, and one-to-one correspond to each other in a physical space. In another specific embodiment, based on suitable wiring paths in the logic substrate and the storage substrate, the logic unit may not be perpendicularly stacked with the corresponding storage block.

The logic units and the storage blocks of the neural network artificial intelligence chip disposed by the above method one-to-one correspond to each other, and data transmission is carried out between the logic units and the corresponding storage blocks, such that a bandwidth for data transmission between the calculation circuit and the entire storage circuit is increased, and thus calculation capabilities of the chip are enhanced.

Further, the storage circuit and the calculation circuit are respectively disposed on different substrates, and are connected by stacking and bonding, such that a connection path between the storage block and the logic unit is reduced. In this way, the connected load capacitor and inductor are both smaller, such that the data transmission rate and bandwidth are both increased, and power consumption is low.

Optionally, the calculation circuit is disposed in a logic substrate, and the storage circuit is disposed in a storage substrate, wherein the storage substrate and the logic substrate are connected by stacking and bonding.

Optionally, the logic unit and the corresponding storage block are electrically connected by an interconnection structure in the logic substrate and the storage substrate.

Optionally, interconnection structures in the logic substrate and the storage substrate are designed so every logic block can electrically connect to one or multiple storage blocks or vice versa.

Optionally, the substrate mentioned can be either silicon substrate with integrated circuits, or silicon carbide substrate with devices built on, or silicon substrate with aluminum nitride and gallium nitride device structures.

Optionally, the storage circuit is disposed in a single storage substrate or a plurality of storage substrates connected by stacking.

Optionally, the calculation circuit is disposed in a single logic substrate or a plurality of logic substrates connected by stacking.

Optionally, the storage circuit is at least one of a DRAM storage circuit, an MRAM storage circuit or a PRAM storage circuit.

Optionally, the neural network artificial intelligence chip further includes: storage logic circuits one-to-one correspondingly connected to the storage blocks, wherein the storage logic circuit is disposed in the storage substrate of the storage block or disposed in the a storage circuit substrate, wherein the storage circuit substrate is connected to the storage substrate by stacking and bonding.

Optionally, each logic unit includes a multiplier, an accumulator, an operation logic circuit and a latch.

Optionally, the storage circuit is disposed in a storage substrate and the calculation circuit is disposed in a logic substrate, wherein the storage substrate and the logic substrate is connected by stacking and bonding to implement one-to-one corresponding connection between the plurality of logic units and the plurality of storage blocks.

Optionally, the storage circuit is disposed in a single storage substrate or a plurality of storage substrates connected by stacking.

Optionally, the calculation circuit is disposed in a single logic substrate or a plurality of logic substrates connected by stacking.

Optionally, the storage circuit is at least one of a DRAM storage circuit, an MRAM storage circuit or a PRAM storage circuit.

The various operations of methods described above may be p by any suitable means capable of the corresponding functions. The means may include various hardware and/or software component(s) and/or module(s), including, but not limited to, a circuit, an application specific integrated circuit (ASIC), or processor.

As used herein, the term “determining” encompasses a wide variety of actions. For example, “determining” may include calculating, computing, processing, deriving, investigating, looking up (e.g., looking up in a table, a database, or another data structure), ascertaining, and the like. Additionally, “determining” may include receiving (e.g., receiving information), accessing (e.g., accessing data in a memory), and the like. Furthermore, “determining” may include resolving, selecting, choosing, establishing, and the like.

As used herein, a phrase referring to “at least one of” a list of items refers to any combination of those items, including single members. As an example, “at least one of: a, b, or c” is intended to cover: a, b, c, a-b, a-c, b-c, and a-b-c.

The various illustrative logical blocks, sub-modules, units, and circuits described in connection with the present disclosure may be implemented or performed with a general-purpose processor, a digital signal processor (DSP), an application specific integrated circuit (ASIC), a field programmable gate array signal (FPGA) or other programmable logic device (PLD), discrete gate or transistor logic, discrete hardware components or any combination thereof designed to perform the functions described herein. A general-purpose processor may be a microprocessor, but in the alternative, the processor may be any commercially available processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

Described above are preferred examples of the present disclosure. It should be noted that persons of ordinary skill in the art may derive other improvements or refinements without departing from the principles of the present disclosure. Such improvements and refinements shall be deemed as falling within the protection scope of the present disclosure.

What is claimed is:

1. A neural network artificial intelligence chip, comprising:
a storage circuit, wherein the storage circuit comprises a plurality of storage blocks; and
a calculation circuit, wherein the calculation circuit comprises a plurality of logic units, wherein the logic units are correspondingly coupled one-to-one to the storage blocks, wherein at least one logic unit is configured to acquire data in the corresponding storage block and store data to the corresponding storage block.

2. The neural network artificial intelligence chip according to claim 1, wherein the calculation circuit is disposed in a logic substrate, wherein the storage circuit is disposed in a storage substrate, wherein the storage substrate and the logic substrate are coupled by stacking and bonding.

3. The neural network artificial intelligence chip according to claim 2, wherein the logic units and the corresponding storage blocks are coupled by an interconnection structure in the logic substrate and the storage substrate.

4. The neural network artificial intelligence chip according to claim 2, wherein the storage circuit is disposed either in a single storage substrate or in a plurality of storage substrates coupled by stacking.

5. The neural network artificial intelligence chip according to claim 2, wherein the calculation circuit is disposed either in a single logic substrate or in a plurality of logic substrates coupled by stacking.

6. The neural network artificial intelligence chip according to claim 1, wherein the storage circuit is at least one of a dynamic random access memory (DRAM) storage circuit, an magnetoresistive random-access memory (MRAM) storage circuit or a phase-change memory (PRAM) storage circuit.

7. The neural network artificial intelligence chip according to claim 2, further comprising:
storage logic circuits correspondingly coupled one-to-one to the storage blocks, wherein the storage logic circuit is disposed either in the storage substrate of the storage block or in the storage circuit substrate, wherein the storage circuit substrate is coupled to the storage substrate by stacking and bonding.

8. The neural network artificial intelligence chip according to claim 1, wherein at least one logic unit comprises a multiplier, an accumulator, an operation logic circuit, and a latch.

9. A method for forming a neural network artificial intelligence chip, comprising:
forming a calculation circuit, wherein the calculation circuit comprises a plurality of logic units;
forming a storage circuit, wherein the storage circuit comprises a plurality of storage blocks; and
correspondingly coupling one-to-one the plurality of logic units and the plurality of storage blocks.

10. The method for forming a neural network artificial intelligence chip according to claim 9, wherein the storage circuit is disposed in a storage substrate, wherein the calculation circuit is disposed in a logic substrate, wherein the storage substrate and the logic substrate are coupled by stacking and bonding, wherein the plurality of logic units are correspondingly one-to-one coupled to the plurality of storage blocks.

11. The method for forming a neural network artificial intelligence chip according to claim 10, wherein the storage circuit is disposed either in a single storage substrate or in a plurality of storage substrates coupled by stacking.

12. The method for forming a neural network artificial intelligence chip according to claim 10, wherein the calculation circuit is disposed either in a single logic substrate or in a plurality of logic substrates coupled by stacking.

13. The neural network artificial intelligence chip according to claim 1, wherein the storage circuit is at least one of a dynamic random access memory (DRAM) storage circuit, an magnetoresistive random-access memory (MRAM) storage circuit or a phase-change memory (PRAM)storage circuit.
